(19) United States
(12) Patent Application Publication
(10) Pub. No.: US 2025/0274124 A1
(43) Pub. Date: Aug. 28, 2025

(54) LEVEL SHIFTER WITH INDEPENDENT DRIVER

(71) Applicant: TAIWAN SEMICONDUCTOR MANUFACTURING COMPANY LTD., HSINCHU (TW)

(72) Inventor: HYUNSUNG HONG, ONTARIO (CA)

(21) Appl. No.: 18/755,752

(22) Filed: Jun. 27, 2024

Related U.S. Application Data
(60) Provisional application No. 63/558,823, filed on Feb. 28, 2024.

(51) Int. Cl. H03K 19/0185; H03K 3/037; H03K 17/687

(52) U.S. Cl. CPC H03K 19/018521; H03K 3/037; H03K 17/6872

(57) ABSTRACT

An integrated circuit is provided, which includes a level-shifting subcircuit and a driving circuit. The level-shifting subcircuit is configured to generate a first control signal within a first power domain and a second control signal within a second power domain in response to an input voltage signal. The driving circuit is configured to generate an output voltage signal within the first power domain in response to the first control signal and the second control signal. A voltage range of the first power domain differs from that of the second power domain.

### CROSS-REFERENCE TO RELATED APPLICATION(S)

This application claims the benefit of U.S. Provisional Application No. 63/558,823, filed Feb. 28, 2024, the entire disclosure of which is incorporated by reference herein.

### BACKGROUND

As semiconductor technology advances, integrated circuits may feature signals operating at a lower voltage swing than those suitable for external circuits, such as other integrated circuits or discrete electrical components. To address this, an input/output (I/O) circuit is commonly integrated into the chip to convert the low voltage swing signal to a high voltage swing signal recognizable by the external circuit. In certain applications, the integrated circuit incorporates both low voltage transistors (referred to as core or thin-gate transistors) and high voltage transistors (referred to as I/O or thick-gate devices). The core transistors are designed to handle the low voltage swing signal, while the I/O transistors are configured to handle the larger voltage swing signal. Core transistors are sized to handle the low voltage swing signal, but are typically not large enough to handle the larger voltage swing signal. In contrast, I/O transistors are generally larger and occupy more die space compared to low-voltage transistors.

### BRIEF DESCRIPTION OF THE DRAWINGS

Aspects of the present disclosure are best understood from the following detailed description when read with the accompanying figures. It is emphasized that, in accordance with standard practice in the industry, various features are not drawn to scale. In fact, the dimensions of the various features can be arbitrarily increased or reduced for clarity of discussion.

FIG. 1 is a block diagram of a level shifting circuit in accordance with some embodiments of the present disclosure.

FIG. 2A is a schematic diagram of a voltage level-shifting circuit in accordance with some embodiments of the present disclosure.

FIG. 2B is a schematic diagram of a voltage level-shifting circuit in accordance with still some embodiments of the present disclosure.

FIG. 2C is a waveform diagram of various voltage signals within the voltage level-shifting circuit in FIG. 2A.

FIG. 3A is a schematic diagram of a voltage level-shifting circuit in accordance with some embodiments of the present disclosure.

FIG. 3B is a schematic diagram of a voltage level-shifting circuit in accordance with still some embodiments of the present disclosure.

FIG. 3C is a waveform diagram of various voltage signals within the voltage level-shifting circuit in FIG. 3A.

FIG. 4A is a schematic diagram of a voltage level-shifting circuit in accordance with some embodiments of the present disclosure.

FIG. 4B is a schematic diagram of a voltage level-shifting circuit in accordance with still some embodiments of the present disclosure.

FIG. 4C is a waveform diagram of various voltage signals within the voltage level-shifting circuit in FIG. 4A.

FIG. 5A is a schematic diagram of a voltage level-shifting circuit in accordance with some embodiments of the present disclosure.

FIG. 5B is a schematic diagram of a voltage level-shifting circuit in accordance with still some embodiments of the present disclosure.

FIG. 5C is a waveform diagram of various voltage signals within the voltage level-shifting circuit in FIG. 5A.

FIG. 6 is a flowchart of a method for operating a level shifting circuit in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features can be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, it will be understood that when an element is referred to as being “connected to” or “coupled to” another element, it can be directly connected to or coupled to the other element, or intervening elements can be present.

Embodiments, or examples, illustrated in the drawings are disclosed as follows using specific language. It will nevertheless be understood that the embodiments and examples are not intended to be limiting. Any alterations or modifications in the disclosed embodiments, and any further applications of the principles disclosed in this document are contemplated as would normally occur to one of ordinary skill in the pertinent art.

Further, it is understood that several processing steps and/or features of a device can be only briefly described. Also, additional processing steps and/or features can be added, and certain of the following processing steps and/or features can be removed or changed while still implementing the claims. Thus, it is understood that the following descriptions represent examples only, and are not intended to suggest that one or more steps or features are required.

In addition, the present disclosure may repeat reference numerals and/or letters in the various examples. This repetition is for the purpose of simplicity and clarity and does not in itself dictate a relationship between the various embodiments and/or configurations discussed.

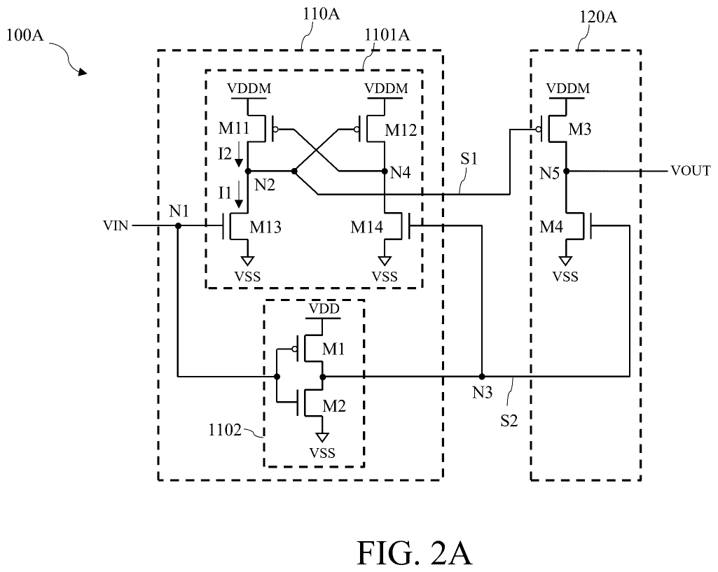

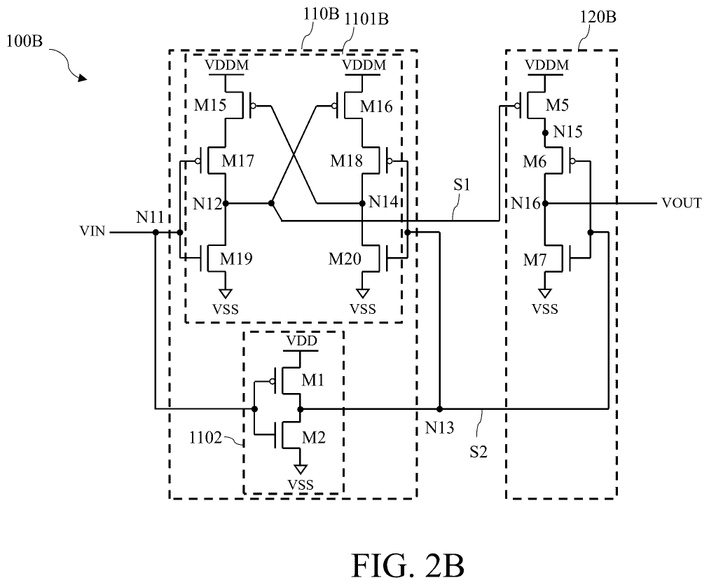

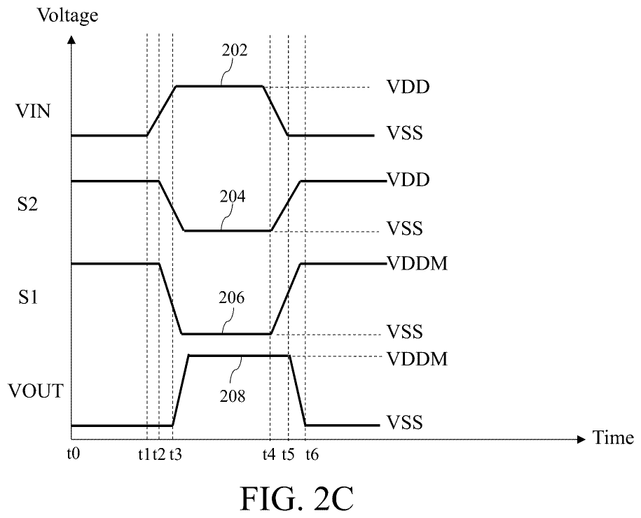

In some embodiments, a level shifting circuit including a level-shifting subcircuit followed by a driving circuit is provided. The level-shifting subcircuit is configured to convert an input voltage signal within a first power domain to an output voltage signal within a second power domain differing from the first power domain. Additionally, the driving circuit includes a voltage pull-up device and a voltage pull-down device that are controlled by a first control signal and a second control signals in different power domains. In the following embodiments, Vtn and Vtp may denote the threshold voltages of N-type transistors and P-type transistors within FIGS. 2A-2B, 3A-3B, 4A-4B, and 5A-5B, respectively. Additionally, Vtn is a positive voltage, and Vtp is a negative voltage.

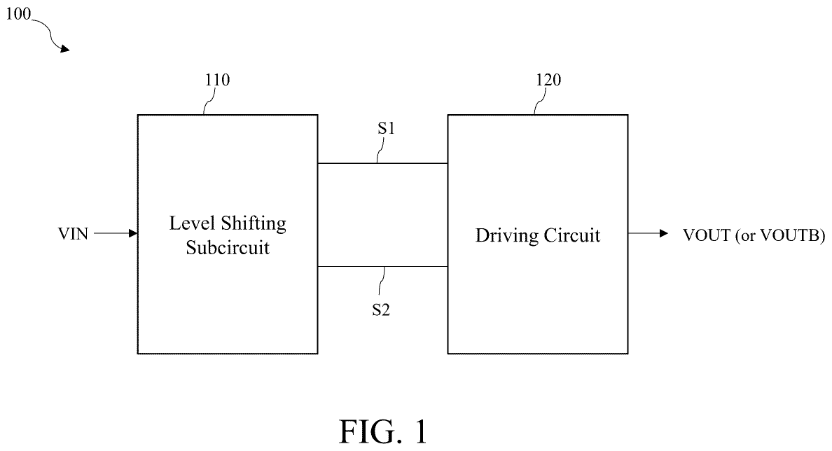

FIG. 1 is a block diagram of a level shifting circuit in accordance with some embodiments of the present disclosure.

In some embodiments, the level shifting circuit 100, also known as a level shifter, level converter, logic level shifter, or voltage level translator, is a circuit used to translate signal from one logic level or voltage domain to another, allowing compatibility between integrated circuits with different voltage requirements. In some embodiments, the level shifting circuit 100 may be a unidirectional level up-shifting circuit which converts the voltage level (e.g., power supply voltage VDD) of the input voltage signal to an output voltage signal or its inverted version with a higher voltage level (e.g., power supply voltage VDDM). In still some embodiments, the level shifting circuit 100 may be a level down-shifting circuit which converts the voltage level (e.g., reference voltage VSS, such as 0V or a negative voltage) of the input voltage signal to an output voltage signal or its inverted version with a lower voltage level (e.g., reference voltage VSSM).

In some embodiments, the level shifting circuit 100 includes a level-shifting subcircuit 110 and a driving circuit 120, as depicted in FIG. 1. In some embodiments, the level-shifting subcircuit 110 is configured to convert an input voltage signal within a first power domain to an intermediate voltage signal within a second power domain differing from the first power domain. The driving circuit 120 is configured to generate an output voltage signal within the second power domain with an enhanced driving capability in either the voltage push-up duration and/or the voltage pull-down duration. The driving circuit 120 may be controlled by control signals S1 and S2 generated by the level-shifting subcircuit 110, while the control signals S1 and S2 may vary depending on the types of the level shifting circuit 100, such as level up-shifting or level down-shifting. The details thereof will be described as follows.

FIG. 2A is a schematic diagram of a voltage level-shifting circuit in accordance with some embodiments of the present disclosure. FIG. 2B is a schematic diagram of a voltage level-shifting circuit in accordance with still some embodiments of the present disclosure. FIG. 2C is a waveform diagram of various voltage signals within the voltage level-shifting circuit in FIG. 2A.

In some embodiments, the level shifting circuit 100A is a unidirectional level up-shifting circuit which includes a level-shifting subcircuit 110A and a driving circuit 120A, as depicted in FIG. 2A. The level-shifting subcircuit 110A includes transistors M1-M2 and M11-M14, while the driving circuit 120A includes transistors M3 and M4. Transistors M11-M14 form a latch circuit 1101A (e.g., a cross-coupled latch circuit), and transistors M1-M2 form an inverter 1102. In some embodiments, node N2 can be regarded as an inverted output terminal of the latch circuit 1101A since the voltage at node N2 (e.g., signal S1) is an inverted version of the input voltage signal VIN. Additionally, node N4 can be regarded as a non-inverted output terminal of the latch circuit 1101A since the voltage at node N4 is a non-inverted version of the input voltage signal VIN.

In some embodiments, the level-shifting function of the level-shifting subcircuit 110A can work normally with appropriate design of the W/L ratios of the P-type transistors M11-M12 and N-type transistors M13-M14, such as the ratio between the W/L (width-to-length) ratio (W/L)ₙ of N-type transistors M13-M14 and the W/L ratio (W/L)ₚ of P-type transistors M11-M12 is greater than a particular value, so that the driving capability of the N-type transistors M13-M14 is higher than that of P-type transistors M11-M12.

The working principle of the level-shifting subcircuit 110A are described as follows. When the input voltage signal VIN is initially at the reference voltage VSS, transistor M13 is turned off. Additionally, the voltage at node N3 (e.g., signal S2) is at the power supply voltage VDD, and thus transistors M14 and M4 are turned on, pulling down the voltage at node N4 and the output voltage VOUT at node N5 to the reference voltage VSS through transistors M14 and M4, respectively. At this time, transistor M11 is turned on, and the voltage at node N2 (e.g., signal S1) is pulled up to the power supply voltage VDDM (e.g., higher than VDD), turning off transistor M3.

On the other hand, when the input voltage signal is at the power supply voltage VDD, transistor M13 is turned on, pulling down the voltage at node N2 (e.g., signal S1) to the reference voltage VSS. At this time, transistor M3 is turned on, pulling up the output voltage VOUT at node N5 to the power supply voltage VDDM. It should be noted that the aforementioned procedure describes the stable-state operations of the level shifting circuit 100A, and the transient operations of the transistors M11 to M14 are described with reference to FIG. 2C as follows.

Specifically, when the input voltage signal VIN is 0V, the gate-to-source voltage Vgs of transistor M11 is kept at approximately the power supply voltage VDDM. As a result, the drain-to-source Vds of transistor M11 is approximately equal to 0V, turning off transistor M11 (i.e., transistor M11 is in the cut-off region). When the input voltage signal VIN is pulled up to the power supply voltage VDD from the reference voltage VSS from time t1, transistor M13 is turned on, so the voltage at node N2 is slightly pulled down by transistor M13 at the beginning, resulting in an increase of the drain-to-source voltage Vds of transistor M11. Accordingly, transistor M11 enters the deep triode region at this time, which has a very small current I2 from the power supply voltage VDDM to node N2. Additionally, transistor M13 is in the saturation region, which has a large current I1 to discharge the electric charges stored within the parasitic capacitance at node N2 to the ground node of the reference voltage VSS.

It should be noted that, with appropriate design of the W/L ratio

$${( \frac{W}{L} )}_{n}$$

of N-type transistors M13-M14 and the W/L ratio

$${( \frac{W}{L} )}_{p}$$

of P-type transistors M11-M12, the current I1 is higher than the current I2 during discharging of the voltage at node N2, and the driving capability caused by current I1 is higher than the driving capability caused by current I2. While discharging the voltage at node N2 starts from time t2, the voltage at node N2 (e.g., signal S1) becomes lower and lower. Accordingly, the drain-to-source Vds of transistor M13 becomes lower, and the drain-to-source Vds of transistor M11 becomes higher due to the channel length modulation effect, so that the current I1 becomes smaller and current I2 become larger. Upon the voltage at node N2 being lower than the power supply voltage VDDM by a threshold voltage Vtp of transistor M12 (i.e., at time t3), transistors M12 and M3 are turned on, and the voltage at node N4 and the output voltage VOUT at node N5 are pulled up to the power supply voltage VDDM. Accordingly, transistor M11 is turned off, and the voltage at node N2 (i.e., signal S1) is discharged to the reference voltage VSS through transistor M13.

The input voltage signal VIN is pulled down from the power supply voltage VDDM to the reference voltage VSS from time t4. Upon the input voltage signal VIN being lower than the threshold voltage Vtn, transistor M13 is turned off. Additionally, the voltage at node N3 (e.g., signal S2) is also pulled up to the power supply voltage VDD from time t4. Upon the voltage at node N3 being higher than the threshold voltage Vtn of transistors M14 and M4, transistor M14 and M4 are turned on, pulling down the voltage at node N4. It should be noted that the driving capability of transistor M14 is strong than that of transistor M12, thereby discharging the electric charges stored within the parasitic capacitance at node N4 through transistor M14, and decreasing the voltage at node N4.

It should be noted that there are no particular constraints for the size or W/L ratio of transistors M3 and M4 within the driving circuit 120A, indicating that transistors M3 and M4 can be designed with large W/L ratios

$${( \frac{W}{L} )}_{p} and {( \frac{W}{L} )}_{n} ,$$

respectively, thereby providing better driving capability for both the voltage push-up duration and voltage pull-down duration of the output voltage VOUT at node N5. In other words, the driving capabilities of transistor M3 and M4 can be in any relationship for the circuit design of the driving circuit 120, such as transistors M3 or M4 having a higher driving capability, or both transistors M3 and M4 having substantially equal driving capability. For simplicity, transistors M3 and M4 have substantially equal driving capability, and the output voltage VOUT at node N5 could be maintained at the same voltage level from time t4.

Upon the voltage at node N4 being lower than the power supply voltage VDDM by the threshold voltage Vtp of transistor M11 (e.g., at time t4), transistor M11 is turned on, pulling up the voltage at node N2 (e.g., signal S1) to the power supply voltage VDDM. Upon the voltage at node N2 being lower than the power supply voltage VDDM by the threshold Vtp of transistor M3 (e.g., at time t5), transistor M3 is turned off. Since transistor M3 is turned off and transistor M4 is turned on at time t5, the output voltage VOUT is pulled down to the reference voltage VSS from time t5 (i.e., regardless of whether transistor M3 or M4 has a higher driving capability, or both have substantially equal driving capability). Accordingly, the output voltage VOUT at node N5 is discharged to the reference voltage at time t6.

On the other hand, when the W/L ratio

$${( \frac{W}{L} )}_{n}$$

of N-type transistors M13-M14 and the W/L ratio

$${( \frac{W}{L} )}_{p}$$

of P-type transistors M11-M12 are not appropriately designed, the driving capability of P-type transistors M11-M12 can be equal to or higher than that of N-type transistors, resulting in the voltage at node N2 being kept at a high voltage level which turns off transistor M12. As a result, the level shifting function of the level-shifting subcircuit 110 could not work normally in this situation. In some approaches, the voltage level-shifting circuit does not include an independent driving circuit as the driving circuit 120 of the level shifting circuit 100A in FIG. 1A, and the voltage generated by the latch circuit (e.g., voltage at node N2 or signal S1), which can have a relatively long voltage push-up duration, is used as the output voltage of the voltage level-shifting circuit due the limit of weaker driving capability of the P-type transistors of the latch circuit.

More specifically, in the embodiment of FIG. 2A, signal S1 can be regarded as a level-shifted control signal, which is level shifted to the VDDM domain (e.g., ranging between VDDM and VSS), used to control the voltage pull-up device (e.g., transistor M3) of the driving circuit 120B, while signal S2 can be regarded as an inverted version (e.g., VIN′) of the input voltage signal, which is in the VDD domain (e.g., ranging in VDD and VSS), and used to control the voltage pull-down device (e.g., transistor M4). Moreover, the voltage pull-up duration of the output voltage VOUT can be significantly improved by the voltage pull-up device (e.g., transistor M3) of the driving circuit 120A since the transistor M3 can be designed to have a larger W/L ratio compared to transistors M13 and M14.

Referring to FIG. 2B, in some embodiments, the level shifting circuit 100B includes a level-shifting subcircuit 110B and a driving circuit 120B. The level shifting circuit 100B includes transistors M1-M2 and M15-M20, while the driving circuit 120B includes transistor M5-M7. Additionally, transistors M15-M20 form a latch circuit 1101B (e.g., a cross-coupled latch circuit).

The operations (e.g., including stable state operations and transient operations) of the level-shifting subcircuit 110B shown in FIG. 2B may be similar to those of the level-shifting subcircuit 110A shown in FIG. 2A, with the difference being that two inverters formed by transistors M17 and M19, and M14 and M20 act as the input stage of the latch circuit (e.g. transistor M15-M20), and the gate terminals of transistors M15 and M16 are connected to the output terminals (e.g., nodes N12 and N14) of the inverters formed by transistors M17 and M19, and M14 and M20. In some embodiments, node N12 can be regarded as an inverted output terminal of the latch circuit 1101A since the voltage at node N12 (e.g., signal S1) is an inverted version of the input voltage signal VIN. Additionally, node N14 can be regarded as a non-inverted output terminal of the latch circuit 1101A since the voltage at node N14 is a non-inverted version of the input voltage signal VIN.

Additionally, the operations of the driving circuit 120B shown in FIG. 2B may be similar to those of the driving circuit 120A shown in FIG. 2A, with the difference being that the inverter formed by transistors M6 and M7 may act as the voltage pull-down device, while transistor M5 acts as the voltage pull-up device. Accordingly, the waveforms for signals VIN, S1, S2, and VOUT of the level shifting circuit 100B shown in FIG. 2B can be referred to the waveform of these signals of the level shifting circuit 100A with reference to FIG. 2C.

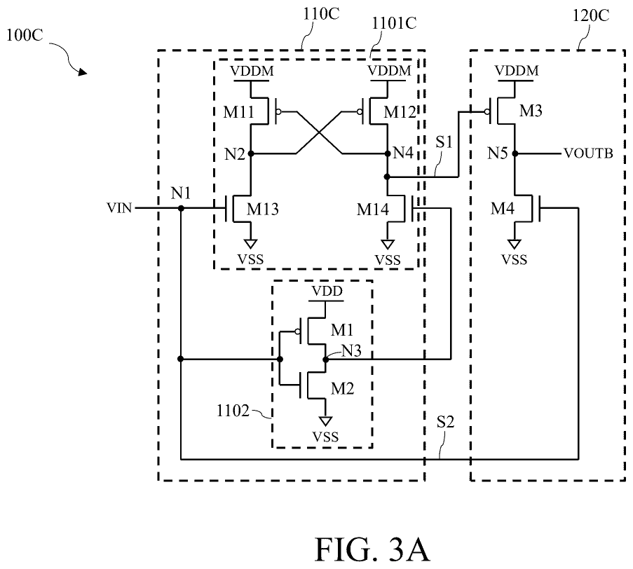

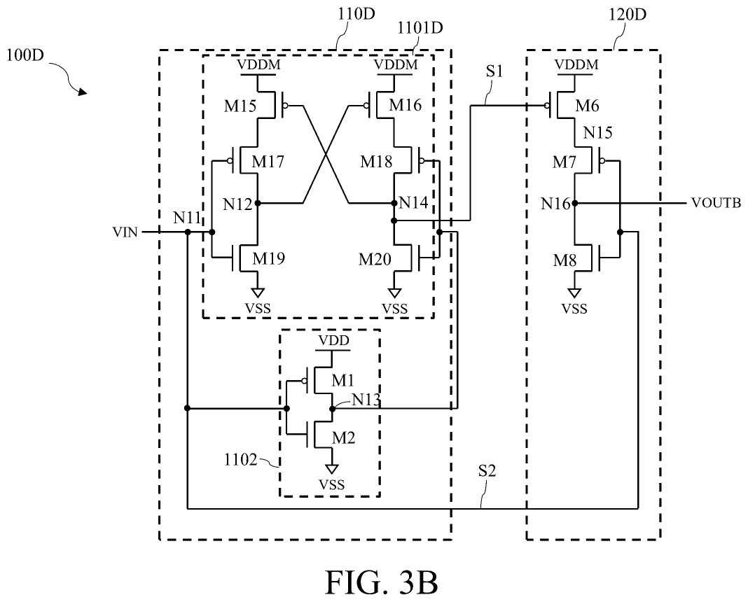

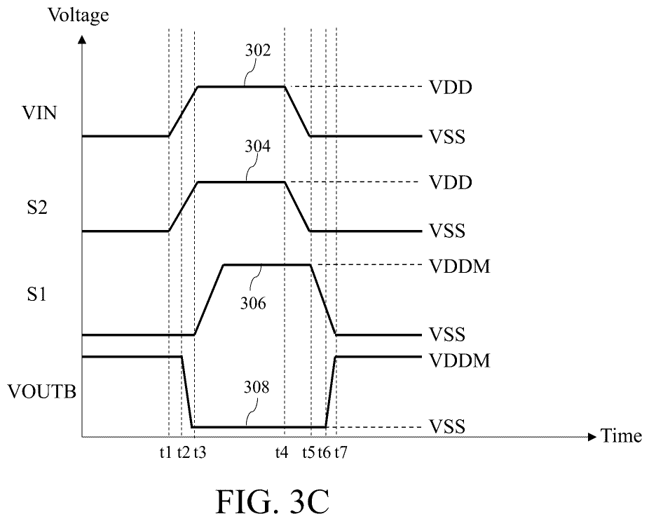

FIG. 3A is a schematic diagram of a voltage level-shifting circuit in accordance with some embodiments of the present disclosure. FIG. 3B is a schematic diagram of a voltage level-shifting circuit in accordance with still some embodiments of the present disclosure. FIG. 3C is a waveform diagram of various voltage signals within the voltage level-shifting circuit in FIG. 3A

In some embodiments, the level shifting circuit 100C is a unidirectional level up-shifting circuit for generating an output voltage signal VOUTB which is in the VDDM domain and inversed to the input voltage signal VIN. The level shifting circuit 100C includes a level-shifting subcircuit 110C and a driving circuit 120C, as depicted in FIG. 3A. The level-shifting subcircuit 110C includes transistors M1-M2 and M11-M14, while the driving circuit 120C includes transistors M3 and M4. Transistors M11-M14 form a latch circuit 1101C, and transistors M1-M2 form an inverter 1102. Similar to the level shifting circuit 100A shown in FIG. 2A, the level-shifting function of the level-shifting subcircuit 110C can work normally with appropriate design of the W/L ratios of the P-type transistors M11-M12 and N-type transistors M13-M14, such as the ratio between the W/L (width-to-length) ratio

$${( \frac{W}{L} )}_{n}$$

of N-type transistors M13-M14 and the W/L ratio

$${( \frac{W}{L} )}_{p}$$

of P-type transistors M11-M12 is greater than a particular value, so that the driving capability of the N-type transistors M13-M14 is higher than that of P-type transistors M11-M12.

The working principle of the level-shifting subcircuit 110C are described as follows. When the input voltage signal VIN is initially at the reference voltage VSS, transistor M13 is turned off. It should be noted that the signal S2 is equivalent to the input voltage signal VIN here, and transistor M4 is also turned off. Additionally, the voltage at node N3 is at the power supply voltage VDD, and thus transistor M14 is turned on, pulling down the voltage at node N4 to the reference voltage VSS through transistor M14. Accordingly, transistor M3 is turned on, pulling up the output voltage VOUTB to the power supply voltage VDDM. At this time, transistor M11 is turned on, and the voltage at node N2 (e.g., signal S1) is pulled up to the power supply voltage VDDM (e.g., higher than VDD), turning off transistor M12.

On the other hand, when the input voltage signal is at the power supply voltage VDD, transistor M13 is turned on, pulling down the voltage at node N2 to the reference voltage VSS. At this time, transistor M12 is turned on, pulling up the voltage at node N4 to the power supply voltage VDDM. Additionally, transistor M4 is also turned on, however, transistor M3 is still turned on until the voltage at node N4 (e.g., signal S1) reaches the voltage VDDM minus the threshold voltage Vtp of transistor M3, resulting in the output voltage VOUTB at node N5 being dependent on the driving capabilities of the voltage pull-up device (e.g., transistor M3) and the voltage pull-down device (e.g., transistor M4) at this time. Upon the voltage at node N4 (e.g., signal S1) reaching the voltage (VDDM-Vtp), transistor M3 is turned off, and the output voltage VOUTB at node N5 is pulled down to the reference voltage VSS. It should be noted that the aforementioned procedure describes the stable-state operations of the level shifting circuit 100C, and the transient operations of the transistors M11 to M14 are described with reference to FIG. 3C as follows.

Specifically, when the input voltage signal VIN is 0V, the gate-to-source voltage Vgs of transistor M11 is kept at approximately the power supply voltage VDDM. As a result, the drain-to-source Vds of transistor M11 is approximately equal to 0V, turning off transistor M11 (i.e., transistor M11 is in the cut-off region). The input voltage signal VIN is pulled up to the power supply voltage VDD from the reference voltage VSS from time t1. Upon the input voltage signal VIN reaching the threshold voltage Vtn at time t2, transistor M13, M2, and M4 are turned on. Accordingly, the output voltage VOUTB at node N5 and the voltage at node N3 are pulled down to the reference voltage VSS from the power supply voltage VDDM through transistors M4 and M2, respectively, turning off transistor M14. When the voltage at node N2 is slightly pulled down by transistor M13 at the beginning, it results in an increase of the drain-to-source voltage Vds of transistor M11. Accordingly, transistor M11 enters the deep triode region at this time, which has a very small current I2 from the power supply voltage VDDM to node N2. At this time, transistor M13 is in the saturation region, which has a large current I1 to discharge the electric charges stored within the parasitic capacitance at node N2 to the ground node of the reference voltage VSS.

When discharging of the electric charges at node N2 continues, the voltage at node N2 gradually decreases from the power supply voltage VDDM. Upon the voltage at node N2 being lower than the power supply voltage VDDM by a threshold voltage Vtp of transistor M12 (i.e., at time t3), transistors M12 is turned on, pulling up the voltage at node N4 (e.g., signal S1) to the power supply voltage VDDM from the reference voltage VSS at time t3. Upon the voltage at node N4 being lower than the power supply voltage VDDM by the threshold voltage Vtp, transistor M11 and M3 are turned off.

The input voltage signal VIN is pulled down from the power supply voltage VDDM to the reference voltage VSS from time t4. Upon the input voltage signal VIN being lower than the threshold voltage Vtn, transistors M13, M2, and M4 are turned off. Upon the voltage at node N3 being higher than the threshold voltage Vtn at time t5, transistor M14 is turned on, pulling down the voltage at node N4 (e.g., signal S1) from the power supply voltage VDDM to the reference voltage VSS. Since the driving capability of transistor M14 is strong than that of transistor M12, the electric charges stored within the parasitic capacitance at node N4 can be discharged through transistor M14, decreasing the voltage at node N4.

Upon the voltage at node N4 being lower than the power supply voltage VDDM by the threshold voltage Vtp at time t6, transistor M3 and M11 are turned on, pulling up the output voltage VOUTB at node N5 and the voltage at node N2 from the reference voltage VSS to the power supply voltage VDDM. At last, the output voltage at node N5 is pulled up to the power supply voltage VDDM at time t7.

More specifically, in the embodiment of FIG. 3A, signal S1 can be regarded as a level-shifted control signal, which is level shifted to the VDDM domain, and used to control the voltage pull-up device (e.g., transistor M3) of the driving circuit 120B, while signal S2 and the input voltage signal are substantially the same, which are in the VDD domain, and signal S2 is used to control the voltage pull-down device (e.g., transistor M4). Moreover, the voltage pull-up duration of the output voltage VOUTB can be significantly improved by the voltage pull-up device (e.g., transistor M3) of the driving circuit 120C since the transistor M3 can be designed to have a larger W/L ratio compared to transistors M13 and M14.

Referring to FIG. 3B, in some embodiments, the level shifting circuit 100D includes a level-shifting subcircuit 110D and a driving circuit 120D. The level shifting circuit 100D includes transistors M1-M2 and M15-M20, while the driving circuit 120D includes transistor M5-M7. Additionally, transistors M15-M20 form a latch circuit 1101D.

The operations (e.g., including stable state operations and transient operations) of the level-shifting subcircuit 110D shown in FIG. 3B may be similar to those of the level-shifting subcircuit 110C shown in FIG. 3A, with the difference being that two inverters formed by transistors M17 and M19, and M14 and M20 act as the differential input stage of the latch circuit (e.g. transistor M15-M20), and the gate terminals of transistors M15 and M16 are connected to the output terminals (e.g., nodes N12 and N14) of the inverters formed by transistors M17 and M19, and M14 and M20. In some embodiments, node N12 can be regarded as an inverted output terminal of the latch circuit 1101D since the voltage at node N12 is an inverted version of the input voltage signal VIN. Additionally, node N14 can be regarded as a non-inverted output terminal of the latch circuit 1101G since the voltage at node N14 (e.g., signal S1) is a non-inverted version of the input voltage signal VIN.

Additionally, the operations of the driving circuit 120D shown in FIG. 3B may be similar to those of the driving circuit 120C shown in FIG. 3A, with the difference being that the inverter formed by transistors M6 and M7 may act as the voltage pull-down device, while transistor M5 acts as the voltage pull-up device. Accordingly, the waveforms for signals VIN, S1, S2, and VOUT of the level shifting circuit 100D shown in FIG. 3B can be referred to the waveform of these signals of the level shifting circuit 100A with reference to FIG. 3C.

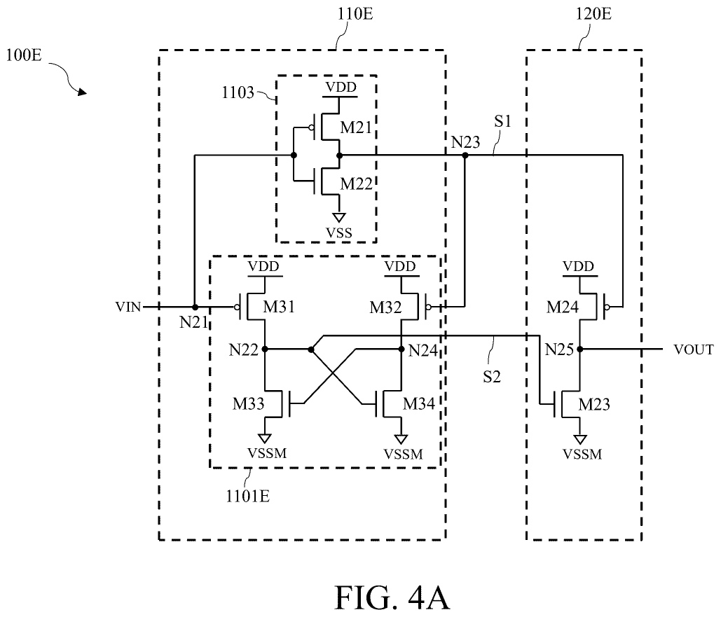

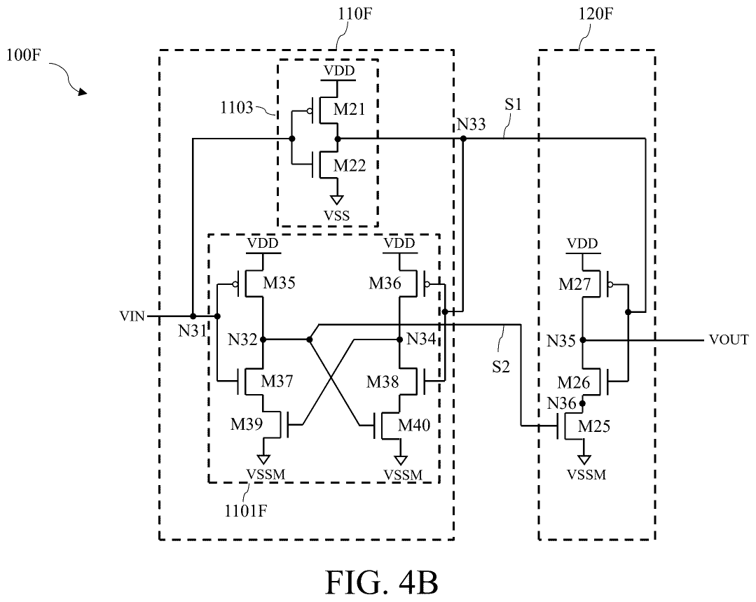

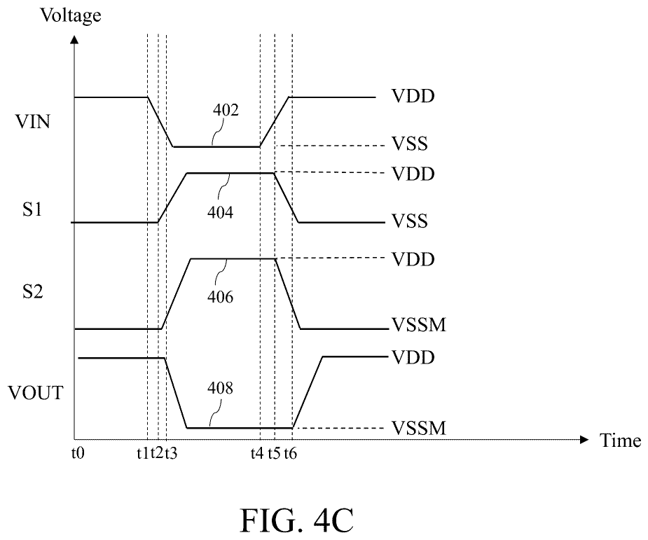

FIG. 4A is a schematic diagram of a voltage level-shifting circuit in accordance with some embodiments of the present disclosure. FIG. 4B is a schematic diagram of a voltage level-shifting circuit in accordance with still some embodiments of the present disclosure. FIG. 4C is a waveform diagram of various voltage signals within the voltage level-shifting circuit in FIG. 4A.

In some embodiments, the level shifting circuit 100E shown in FIG. 4A is a level down-shifting circuit (or negative level shifter) for converting an input voltage signal VIN to an output voltage signal VOUT in the power domain of the reference voltage VSSM. For example, the voltage range of the input voltage signal VIN is between the power supply voltage VDD and the reference voltage VSS, while the voltage range of the output voltage signal VOUT is between the power supply voltage VDD and the reference voltage VSSM, wherein the reference voltage VSSM is lower than the reference voltage VSS. The level shifting circuit 100E includes a level-shifting subcircuit 110E and a driving circuit 120E, as depicted in FIG. 4A. The level-shifting subcircuit 110E includes transistors M21-M22 and M31-M34, while the driving circuit 120E includes transistors M23 and M24. Transistors M31-M34 form a latch circuit 1101E, and transistors M21-M22 form an inverter 1103. In some embodiments, node N22 can be regarded as an inverted output terminal of the latch circuit 1101E since the voltage at node N22 (e.g., signal S2) is an inverted version of the input voltage signal VIN. Additionally, node N24 can be regarded as a non-inverted output terminal of the latch circuit 1101E since the voltage at node N24 is a non-inverted version of the input voltage signal VIN.

The level-shifting function of the level-shifting subcircuit 110C can work normally with appropriate design of the W/L ratios of the P-type transistors M11-M12 and N-type transistors M13-M14, such as the ratio between the W/L ratio

$${( \frac{W}{L} )}_{p}$$

of P-type transistors M31-M32 and the W/L ratio

$${( \frac{W}{L} )}_{n}$$

of N-type transistors M33-M34 is greater than a particular value, so that the driving capability of the P-type transistors M31-M32 is higher than that of the N-type transistors M33-M34.

The working principle of the level-shifting subcircuit 110E are described as follows. When the input voltage signal VIN is initially at the power supply voltage VDD, transistor M21 and transistor M31 are turned off, and transistor M22 is turned on, pulling down the voltage at node N23 to the reference voltage VSS. Accordingly, transistors M24 and M32 are turned on, pulling up the voltage at node N24 and the output voltage VOUT at node 25 to the power supply voltage VDD through transistors M32 and M24, respectively. When the voltage at node N24 is higher than the threshold voltage Vtn, transistor M33 is turned on, pulling down the voltage at node N22 to the reference voltage VSSM. When the voltage at node N22 is lower than the threshold voltage Vtn, transistor M23 is turned off.

On the other hand, when the input voltage signal VIN is at the reference voltage VSS, transistor M21 and M31 are turned on, and transistor M22 is turned off, pulling up the voltage at node N23 (e.g., signal S1) and the voltage at node N22 (e.g., signal S2) to the power supply voltage VDD. Accordingly, transistors M24 and M32 are turned off. At this time, when the voltage at node N22 (e.g., signal S2) is higher than the threshold voltage Vtn, transistor M34 and M23 are turned on, pulling down the voltage at node N24 and the output voltage VOUT at node N25 to the reference voltage VSSM. When the voltage at node N24 is lower than the threshold voltage Vtn, transistor M33 is turned off. It should be noted that the aforementioned procedure describes the stable-state operations of the level shifting circuit 100E, and the transient operations of the transistors M31 to M34 are described with reference to FIG. 4C as follows.

Specifically, when the input voltage signal VIN is initially at the power supply voltage VDD at time t0, the gate-to-source voltage Vgs of transistor M31 is kept at approximately 0V, turning off transistor M31. Afterwards, the input voltage signal VIN is pulled down from the power supply voltage VDD to the reference voltage VSS from time t1. Upon the input voltage signal VIN being lower than the power supply voltage VDD by the threshold voltage Vtp at time t2, transistors M31 and M21 are turned on, pulling up the voltage at node N23 (e.g., signal S1) from the reference voltage VSS to the power supply voltage VDD. It should be noted since the driving capability of transistor M31 is higher than that of transistor M33, the voltage at node N22 (e.g., signal S2) is then pulled up from the reference voltage VSSM to the power supply voltage VDD at time t3.

Furthermore, the input voltage signal VIN is pulled up from the reference voltage VSS to the power supply voltage VDD from time t4. Upon the input voltage signal VIN reaching the voltage (VDD+Vtp) at time t5 (i.e., Vtp is a negative voltage), transistor M21 and M31 are turned off. Since transistor M22 is turned on, the voltage at node N23 (e.g., signal S1) is pulled down to the reference voltage VSS. Upon the voltage at node N23 (e.g., signal S1) being lower than the voltage (VDD+Vtp), transistor M32 and M23 are turned on. It should be noted that the voltage at node N22 (e.g., signal S2) could be higher than the threshold voltage Vtn at this time, and thus transistor M24 is turned on, causing the output voltage VOUT at node N25 is affected by the voltage pull-up device (e.g., transistor M23) and the voltage pull-down device (e.g., transistor M24). Assuming that the driving capabilities of transistor M23 and M24 are substantially equal, the output voltage VOUT at node N25 can be maintained at the reference voltage VSSM. Upon the voltage at node N22 (e.g., signal S2) reaches the voltage (VSSM+Vtn) at time t6, transistor M24 is turned off, and the output voltage VOUT at node N25 is pulled up to the power supply voltage VDD from time t6.

More specifically, in the embodiment of FIG. 4A, signal S1 can be regarded as an inverted input voltage signal, which is within a power domain ranging between the power supply voltage VDD and the reference voltage VSS, and used to control the voltage pull-up device (e.g., transistor M24) of the driving circuit 120E, while signal S2, which is within another power domain ranging between the power supply voltage VDD and the reference voltage VSSM, is used to control the voltage pull-down device (e.g., transistor M23). Moreover, the voltage pull-down duration of the output voltage VOUT can be significantly improved by the voltage pull-down device (e.g., transistor M23) of the driving circuit 120E since the transistor M23 can be designed to have a larger W/L ratio compared to transistors M33 and M34.

Referring to FIG. 4B, in some embodiments, the level shifting circuit 100F includes a level-shifting subcircuit 110F and a driving circuit 120F. The level shifting circuit 100F includes transistors M21-M22 and M35-M40, while the driving circuit 120B includes transistor M25-M27. Additionally, transistors M35-M40 form a latch circuit 1101B.

The operations (e.g., including stable state operations and transient operations) of the level-shifting subcircuit 110F shown in FIG. 4B may be similar to those of the level-shifting subcircuit 110E shown in FIG. 4A, with the difference being that two inverters formed by transistors M35 and M37, and M36 and M38 act as the input stage of the latch circuit (e.g. transistor M35-M40), and the gate terminals of transistors M39 and M40 are connected to the output terminals (e.g., nodes N32 and N34) of the inverters formed by transistors M35 and M37, and M36 and M38. In some embodiments, node N22 can be regarded as an inverted output terminal of the latch circuit 1101F since the voltage at node N32 (e.g., signal S2) is an inverted version of the input voltage signal VIN. Additionally, node N34 can be regarded as a non-inverted output terminal of the latch circuit 1101F since the voltage at node N34 is a non-inverted version of the input voltage signal VIN.

Additionally, the operations of the driving circuit 120F shown in FIG. 4B may be similar to those of the driving circuit 120E shown in FIG. 4A, with the difference being that the inverter formed by transistors M26 and M27 acts as the voltage pull-up device, while transistor M25 acts as the voltage pull-down device. Accordingly, the waveforms for signals VIN, S1, S2, and VOUT of the level shifting circuit 100F shown in FIG. 4B can be referred to the waveform of these signals of the level shifting circuit 100E with reference to FIG. 4C.

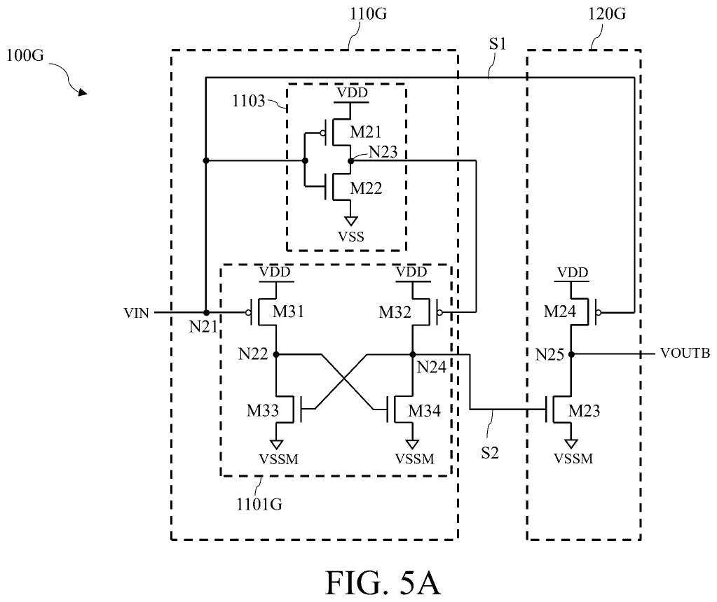

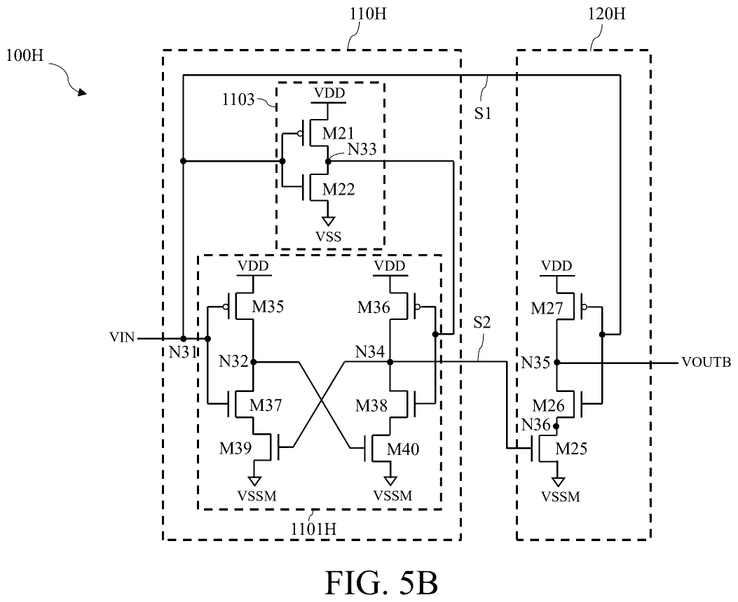

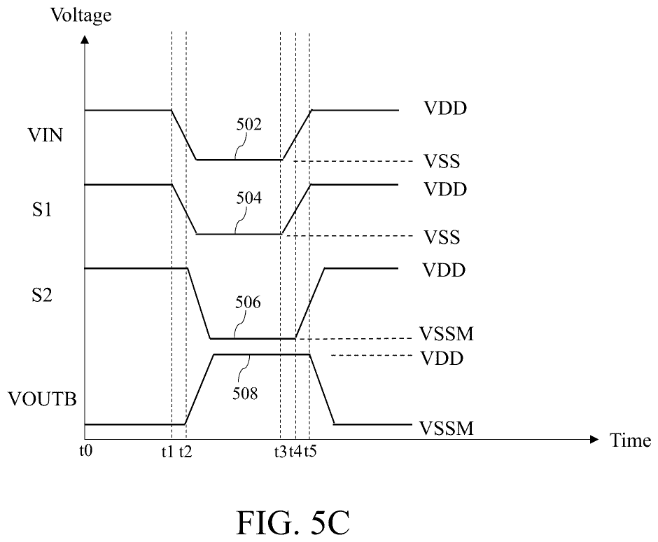

FIG. 5A is a schematic diagram of a voltage level-shifting circuit in accordance with some embodiments of the present disclosure. FIG. 5B is a schematic diagram of a voltage level-shifting circuit in accordance with still some embodiments of the present disclosure. FIG. 5C is a waveform diagram of various voltage signals within the voltage level-shifting circuit in FIG. 5A

In some embodiments, the level shifting circuit 100G is a level down-shifting circuit for generating an output voltage signal VOUTB which ranges between the power supply voltage VDD and the reference voltage VSSM, and is an inverted version of the input voltage signal VIN. The level shifting circuit 100G includes a level-shifting subcircuit 110G and a driving circuit 120G, as depicted in FIG. 5A. The level-shifting subcircuit 110G includes transistors M21-M22 and M31-M34, while the driving circuit 120G includes transistors M23 and M24. Transistors M31-M34 form a latch circuit 1101G, and transistors M21-M22 form an inverter 1103. In some embodiments, node N22 can be regarded as an inverted output terminal of the latch circuit 1101G since the voltage at node N22 is an inverted version of the input voltage signal VIN. Additionally, node N24 can be regarded as a non-inverted output terminal of the latch circuit 1101G since the voltage at node N24 (e.g., signal S2) is a non-inverted version of the input voltage signal VIN.

Similar to the level shifting circuit 100E shown in FIG. 4A, the level-shifting function of the level-shifting subcircuit 110G can work normally with appropriate design of the W/L ratios of the P-type transistors M11-M12 and N-type transistors M13-M14, such as the ratio between the W/L ratio

$${( \frac{W}{L} )}_{p}$$

of P-type transistors M31-M32 and the W/L ratio

$${( \frac{W}{L} )}_{n}$$

of N-type transistors M33-M34 is greater than a particular value, so that the driving capability of the P-type transistors M31-M32 is higher than that of the N-type transistors M33-M34.

The working principle of the level-shifting subcircuit 110G are described as follows. When the input voltage signal VIN (e.g., signal S1) is initially at the power supply voltage VDD, transistor M21 and transistor M31 are turned off, and transistor M22 is turned on, pulling down the voltage at node N23 to the reference voltage VSS. Accordingly, transistors M24 and M32 are turned on, pulling up the voltage at node N24 (e.g., signal S2) and the output voltage VOUT at node 25 to the power supply voltage VDD through transistors M32 and M24, respectively. When the voltage at node N24 is higher than the threshold voltage Vtn, transistor M33 is turned on, pulling down the voltage at node N22 to the reference voltage VSSM. When the voltage at node N22 is lower than the threshold voltage Vtn, transistor M23 is turned off.

On the other hand, when the input voltage signal VIN (e.g., signal S1) is at the reference voltage VSS, transistor M21, M31, and M24 are turned on, and transistor M22 is turned off, pulling up the voltage at node N23, the voltage at node N22, and the output voltage VOUTB at node N25 to the power supply voltage VDD. Accordingly, transistor M32 is turned off. At this time, when the voltage at node N22 is higher than the threshold voltage Vtn, transistor M34 is turned on, pulling down the voltage at node N24 (e.g., signal S2) to the reference voltage VSSM. When the voltage at node N24 is lower than the threshold voltage Vtn, transistors M33 and M23 are turned off. It should be noted that the aforementioned procedure describes the stable-state operations of the level shifting circuit 100G, and the transient operations of the transistors M31 to M34 are described with reference to FIG. 5C as follows.

Specifically, when the input voltage signal VIN (e.g., signal S1) is initially at the power supply voltage VDD at time t0, the gate-to-source voltage Vgs of transistor M31 is kept at approximately 0V, turning off transistor M31. Afterwards, the input voltage signal VIN is pulled down from the power supply voltage VDD to the reference voltage VSS from time t1. Upon the input voltage signal VIN being lower than the voltage (VDD+Vtp) at time t2, transistors M21, M31 and M24 are turned on, and transistor M22 is turned off, pulling up the voltage at node N23, the voltage at node N22, and the output voltage VOUTB at node N25 to the power supply voltage VDD. It should be noted since the driving capability of transistor M31 is higher than that of transistor M33, the voltage at node N22 (e.g., signal S2) is pulled up from the reference voltage VSSM to the power supply voltage VDD at time t2.

Furthermore, the input voltage signal VIN (e.g., signal S1) is pulled up from the reference voltage VSS to the power supply voltage VDD from time t3. Upon the input voltage signal VIN reaching the voltage (VDD+Vtp), transistor M21 and M31 are turned off. Since transistor M22 is turned on, the voltage at node N23 is pulled down to the reference voltage VSS. Upon the voltage at node N23 being lower than the voltage (VDD+Vtp) at time t4, transistor M32 and M23 are turned on, pulling up the voltage at node N24 (e.g., signal S2) from the reference voltage VSSM to the power supply voltage VDD. Upon the voltage at node 24 (e.g., signal S2) reaching the voltage (VSSM+Vtn) at time t5, transistor M23 is turned on, pulling down the output voltage VOUTB at node N25 from the power supply voltage VDD to the reference voltage VSSM.

More specifically, in the embodiment of FIG. 5A, the input voltage signal VIN can be regarded as the signal S1, which ranges between the power supply voltage VDD and the reference voltage VSS, and used to control the voltage pull-up device (e.g., transistor M24) of the driving circuit 120G, while signal S2, which ranges between the power supply voltage VDD and the reference voltage VSSM, is used to control the voltage pull-down device (e.g., transistor M23). Moreover, the voltage pull-down duration of the output voltage VOUTB can be significantly improved by the voltage pull-down device (e.g., transistor M23) of the driving circuit 120G since the transistor M23 can be designed to have a larger W/L ratio compared to transistors M33 and M34.

Referring to FIG. 5B, in some embodiments, the level shifting circuit 100H includes a level-shifting subcircuit 110H and a driving circuit 120H. The level shifting circuit 100F includes transistors M21-M22 and M35-M40, while the driving circuit 120B includes transistor M25-M27. Additionally, transistors M35-M40 form a latch circuit 1101B.

The operations (e.g., including stable state operations and transient operations) of the level-shifting subcircuit 110H shown in FIG. 5B may be similar to those of the level-shifting subcircuit 110G shown in FIG. 5A, with the difference being that two inverters formed by transistors M35 and M37, and M36 and M38 act as the input stage of the latch circuit (e.g. transistor M35-M40), and the gate terminals of transistors M39 and M40 are connected to the output terminals (e.g., nodes N32 and N34) of the inverters formed by transistors M35 and M37, and M36 and M38. In some embodiments, node N22 can be regarded as an inverted output terminal of the latch circuit 1101H since the voltage at node N32 is an inverted version of the input voltage signal VIN. Additionally, node N34 can be regarded as a non-inverted output terminal of the latch circuit 1101H since the voltage at node N34 (e.g., signal S2) is a non-inverted version of the input voltage signal VIN.

Additionally, the operations of the driving circuit 120H shown in FIG. 5B may be similar to those of the driving circuit 120G shown in FIG. 5A, with the difference being that the inverter formed by transistors M26 and M27 acts as the voltage pull-up device, while transistor M25 acts as the voltage pull-down device. Accordingly, the waveforms for signals VIN, S1, S2, and VOUT of the level shifting circuit 100G shown in FIG. 5B can be referred to the waveform of these signals of the level shifting circuit 100G with reference to FIG. 4C.

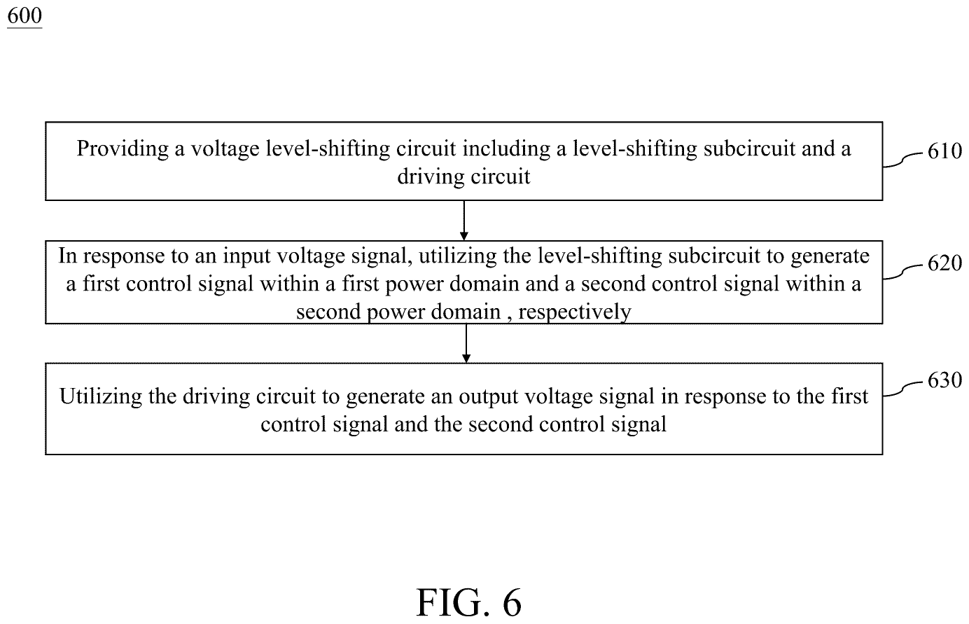

FIG. 6 is a flowchart of a method for operating a level shifting circuit in accordance with some embodiments of the present disclosure.

In operation 610, a voltage level-shifting circuit including a level-shifting subcircuit and a driving circuit is provided. In the embodiment of FIG. 1, the level shifting circuit 100 includes a level-shifting subcircuit 110 and a driving circuit 120. Additionally, the level shifting circuit 100 could be a level up-shifting circuit or a level down-shifting circuit, as described in the embodiments of FIGS. 2 to 5.

In operation 620, in response to an input voltage signal, a first control signal and a second control signal are generated by the level-shifting subcircuit, respectively. A first power domain of the first control signal is wider than a second power domain of the second power domain. In the embodiment of FIG. 1, the level shifting circuit 100 is configured to convert an input voltage signal VIN within the first power domain to an output voltage signal VOUT or VOUTB within the second power domain, wherein the voltage range of the second power domain is wider than that of the first power domain. For example, in the embodiments of FIGS. 2 to 3, the level shifting circuit 100 is a level up-shifting circuit, and the first control signal S1 and the second control signal S2 may be in the second power domain and the first power domain, respectively, where the voltage range of the first power domain is between the power supply voltage VDD and the reference voltage VSS, and the voltage range of the second power domain is between the power supply voltage VDDM (i.e., higher than VDD) and the reference voltage VSS. Additionally, in the embodiments of FIGS. 4 to 5, the level shifting circuit 100 is a level down-shifting circuit, and the first control signal S1 and the second control signal S2 may be in the first power domain and the second power domain, respectively, where the voltage range of the first power domain is between the power supply voltage VDD and the reference voltage VSS, and the voltage range of the second power domain is between the power supply voltage VDD and the reference voltage VSSM (i.e., lower than VSS).

In operation 630, the driving circuit is utilized to generate an output voltage signal using the first control signal and the second control signal. In the embodiments of FIGS. 2 to 5, the first control signal S1 and the second control signal S2 may be used to control the voltage pull-up device and the voltage pull-down device within the driving circuit 120. Since the level shifting circuit 100 can generate the output voltage signal VOUT or VOUTB using the independent driving circuit 120, which includes voltage pull-up device and the voltage pull-down device having larger sizes (e.g., W/L ratios) and controlled by the first control signal S1 and second control signal S2 within different power domains, thereby improving the voltage push-up duration and/or voltage pull-down duration of the output voltage signal VOUT or VOUTB.

An aspect of the present disclosure provides an integrated circuit, which includes a level-shifting subcircuit and a driving circuit. The level-shifting subcircuit is configured to generate a first control signal within a first power domain and a second control signal within a second power domain in response to an input voltage signal. The driving circuit is configured to generate an output voltage signal within the first power domain in response to the first control signal and the second control signal. A voltage range of the first power domain differs from that of the second power domain.

Another aspect of the present disclosure provides an integrated circuit, which includes a level-shifting subcircuit and a driving circuit. The level-shifting subcircuit is configured to generate a first control signal within a first power domain and a second control signal within a second power domain in response to an input voltage signal. The driving circuit is configured to generate an output voltage signal within the first power domain in response to the first control signal and the second control signal. A voltage range of the first power domain differs from that of the second power domain.

Yet another aspect of the present disclosure provides a method. The method includes the following steps: providing a voltage level-shifting circuit including a level-shifting subcircuit and a driving circuit; in response to an input voltage signal, utilizing the level-shifting subcircuit to generate a first control signal and a second control signal, respectively; and utilizing the driving circuit to generate an output voltage signal using the first control signal and the second control signal, wherein a first power domain of the first control signal is wider than a second power domain of the second control signal.

The methods and features of the present disclosure have been sufficiently described in the provided examples and descriptions. It should be understood that any modifications or changes without departing from the spirit of the present disclosure are intended to be covered in the protection scope of the present disclosure.

Moreover, the scope of the present application is not intended to be limited to the particular embodiments of the process, machine, manufacture, and composition of matter, means, methods and steps described in the specification. As those skilled in the art will readily appreciate from the present disclosure, processes, machines, manufacture, composition of matter, means, methods or steps presently existing or later to be developed, that perform substantially the same function or achieve substantially the same result as the corresponding embodiments described herein, can be utilized according to the present disclosure.

Accordingly, the appended claims are intended to include within their scope processes, machines, manufacture, compositions of matter, means, methods or steps. In addition, each claim constitutes a separate embodiment, and the combination of various claims and embodiments are within the scope of the present disclosure.

What is claimed is:

1. An integrated circuit, comprising:
a level-shifting subcircuit, configured to generate a first control signal within a first power domain and a second control signal within a second power domain in response to an input voltage signal; and
a driving circuit, configured to generate an output voltage signal within the first power domain in response to the first control signal and the second control signal,
wherein a voltage range of the first power domain differs from that of the second power domain.

2. The integrated circuit of claim 1, wherein the level-shifting subcircuit comprises a cross-coupled latch circuit and a first inverter, and the driving circuit comprises a voltage pull-up device and a voltage pull-down device.

3. The integrated circuit of claim 2, wherein:
the first inverter is coupled between a first power supply voltage and a reference voltage which constitute the second power domain;
the cross-coupled latch circuit is coupled between a second power supply voltage and the reference voltage which constitute the first power domain;
the second power supply voltage is higher than the first power supply voltage; and
the voltage pull-up device and the voltage pull-down device are controlled by the first control signal and the second control signal, respectively.

4. The integrated circuit of claim 3, wherein the first control signal is generated at an inverted output terminal of the cross-coupled latch circuit, and the second control signal is an inverted signal of the input voltage signal.

5. The integrated circuit of claim 3, wherein the first control signal is generated at a non-inverted output terminal of the cross-coupled latch circuit, and the second control signal is the input voltage signal.

6. The integrated circuit of claim 3, wherein a voltage pull-up driving capability of the voltage pull-up device is stronger than that of the cross-coupled latch circuit.

7. The integrated circuit of claim 2, wherein
the cross-coupled latch circuit is coupled between a power supply voltage and a first reference voltage which constitute the first power domain;
the first inverter is coupled between the power supply voltage and a second reference voltage which constitute the second power domain;
the first reference voltage is lower than the second reference voltage; and
the voltage pull-up device and the voltage pull-down device are controlled by the second control signal and the first control signal, respectively.

8. The integrated circuit of claim 7, wherein the first control signal is generated at an inverted output terminal of the cross-coupled latch circuit, and the second control signal is an inverted signal of the input voltage signal.

9. The integrated circuit of claim 7, wherein the first control signal is generated at a non-inverted output terminal of the cross-coupled latch circuit, and the second control signal is the input voltage signal.

10. The integrated circuit of claim 7, wherein a voltage pull-down driving capability of the voltage pull-down device is stronger than that of the cross-coupled latch circuit.

11. An integrated circuit, comprising:
a level-shifting subcircuit, configured to generate a first control signal and a second control signal in response to an input voltage signal; and
a driving circuit, configured to generate an output voltage signal according to the first control signal and the second control signal,
wherein the first control signal and the second control signal are within different power domains, and a voltage range of the output voltage signal is wider than that of the input voltage signal.

12. The integrated circuit of claim 11, wherein the level-shifting subcircuit comprises a cross-coupled latch circuit and a first inverter, and the driving circuit comprises a first voltage pull-up device and a first voltage pull-down device.

13. The integrated circuit of claim 12, wherein:
the first inverter is coupled between a first power supply voltage and a reference voltage which constitute a first power domain;
the cross-coupled latch circuit is coupled between a second power supply voltage and the reference voltage which constitute a second power domain;
the second power supply voltage is higher than the first power supply voltage; and
the first voltage pull-up device and the first voltage pull-down device are controlled by the first control signal and the second control signal, respectively.

14. The integrated circuit of claim 13, wherein:
the cross-coupled latch circuit comprises a plurality of second voltage pull-up devices and a plurality of second voltage pull-down devices;
a size of the first voltage pull-up device is larger than that of the second voltage pull-up devices; and
a size of the first voltage pull-down device is substantially equal to that of the second voltage pull-down devices.

15. The integrated circuit of claim 12, wherein:
the cross-coupled latch circuit is coupled between a power supply voltage and a first reference voltage which constitute a first power domain;
the first inverter is coupled between the power supply voltage and a second reference voltage which constitute a second power domain;
the first reference voltage is lower than the second reference voltage; and
the first voltage pull-up device and the first voltage pull-down device are controlled by the second control signal and the first control signal, respectively.

16. The integrated circuit of claim 15, wherein:
the cross-coupled latch circuit comprises a plurality of second voltage pull-up devices and a plurality of second voltage pull-down devices;
a size of the first voltage pull-up device is substantially equal to that of the second voltage pull-up devices; and
a size of the first voltage pull-down device is greater than that of the second voltage pull-down devices.

17. A method, comprising:
providing a voltage level-shifting circuit including a level-shifting subcircuit and a driving circuit;
in response to an input voltage signal, utilizing the level-shifting subcircuit to generate a first control signal and a second control signal, respectively; and
utilizing the driving circuit to generate an output voltage signal using the first control signal and the second control signal,
wherein a first power domain of the first control signal is wider than a second power domain of the second control signal.

18. The method of claim 17, wherein:
the first power domain ranges between a first power supply voltage and a reference voltage;
the second power domain ranges between a second power supply voltage and the reference voltage; and
the first power supply voltage is higher than the second power supply voltage.

19. The method of claim 17, wherein:
the first power domain ranges between a power supply voltage and a first reference voltage;
the second power domain ranges between the power supply voltage and a second reference voltage; and
the first reference voltage is lower than the second reference voltage.

20. The method of claim 17, wherein a driving capability of the driving circuit is higher than that of the level-shifting subcircuit.
